(19) United States
(12) Patent Application Publication
(10) Pub. No.: US 2025/0255046 A1
(43) Pub. Date: Aug. 7, 2025

(54) LIGHT EMITTING DIODE

(71) Applicant: Xiamen San'an Optoelectronics Co., Ltd., Fujian (CN)

(72) Inventors: Xiushan ZHU, Fujian (CN); Yan LI, Fujian (CN); Ji CHEN, Fujian (CN); Qi JING, Fujian (CN); Zhilong LU, Fujian (CN); Chi-ming TSAI, Fujian (CN); Juchin TU, Fujian (CN); Chung-ying CHANG, Fujian (CN)

(73) Assignee: Xiamen San'an Optoelectronics Co., Ltd., Fujian (CN)

(21) Appl. No.: 19/186,549

(22) Filed: Apr. 22, 2025

Related U.S. Application Data
(63) Continuation of application No. PCT/CN2022/128485, filed on Oct. 31, 2022.

(51) Int. Cl. H10H 20/832; H10H 20/01; H10H 20/84

(52) U.S. Cl. CPC H10H 20/835; H10H 20/032; H10H 20/034; H10H 20/84

(57) ABSTRACT

A light emitting diode is provided. The light emitting diode includes: a semiconductor stack, including a first semiconductor layer, a second semiconductor layer, and an active layer located between the first semiconductor layer and the second semiconductor layer; a first insulating layer, formed on the semiconductor stack; a reflective electrode layer, partially formed on the first insulating layer, wherein a minimum distance between an edge of the reflective electrode layer and the semiconductor stack is a fourth distance, and the fourth distance is in a range of 1 μm to 5 μm; and a fourth insulating layer, formed on the reflective electrode layer, wherein the fourth insulating layer is aluminum oxide.

### CROSS-REFERENCE TO RELATED APPLICATION

This application is a continuation of international application of PCT application serial no. PCT/CN2022/128485, filed on Oct. 31, 2022. The entirety of each of the above-mentioned patent applications is hereby incorporated by reference herein and made a part of this specification.

### TECHNICAL FIELD

The disclosure relates to the technical field of light emitting diode manufacturing, and particularly to a light emitting diode.

### BACKGROUND TECHNOLOGY

A light emitting diode (LED) contains different light-emitting materials and light-emitting components. It is a solid-state semiconductor light emitting diode. Due to advantages such as low cost, low power consumption, high luminous efficiency, small size, energy saving, environmental protection, and good optoelectronic characteristics, it is widely used in various applications, including lighting, visible light communication, and light-emitting displays.

### SUMMARY OF INVENTION

### Technical Problem

### Solution to Problem

### Technical Solution

To achieve at least one advantage or other advantages of the disclosure, an embodiment of the disclosure provides a light emitting diode. The light emitting diode includes a semiconductor stack including, from top to bottom, a first semiconductor layer, a second semiconductor layer, and an active layer located between the first semiconductor layer and the second semiconductor layer. The light emitting diode includes a first insulating layer formed on the semiconductor stack. The first insulating layer includes an upper surface away from the semiconductor stack and a lower surface opposite to the upper surface. The upper surface includes a first surface, a second surface, and a third surface connected to the first surface and the second surface. A thickness between the first surface and the lower surface is less than a thickness between the second surface and the lower surface. The light emitting diode includes a reflective electrode layer formed on the first insulating layer. An edge of the reflective electrode layer is formed on the third surface of the first insulating layer. A horizontal distance between the edge of the reflective electrode layer and an edge of the second semiconductor layer is a fourth distance, and the fourth distance is in a range of 1 μm to 5 μm. The light emitting diode includes a fourth insulating layer formed on the reflective electrode layer and extending to the second surface of the first insulating layer. The fourth insulating layer is an aluminum oxide.

### Positive Effects of Invention

### Positive Effects

Other features and beneficial effects of the disclosure will be described in the following specification. Some of them will become apparent from the specification, and some of them may be understood through implementation of the disclosure. The objectives and other beneficial effects of the disclosure may be achieved and obtained through the structures particularly pointed out in the specification, claims, and drawings.

### BRIEF DESCRIPTION OF DRAWINGS

### Description of Drawings

To more clearly describe the technical solutions in the embodiments of the disclosure or the prior art, a brief introduction to the drawings used in the description of the embodiments or the prior art is provided below. It is evident that the drawings described below correspond to some embodiments of the disclosure. For a person having ordinary skill in the art, other drawings may be obtained from these drawings without creative effort. In the following description, unless otherwise specified, the positional relationships described for the drawings are based on the directions shown in the illustrations of the components.

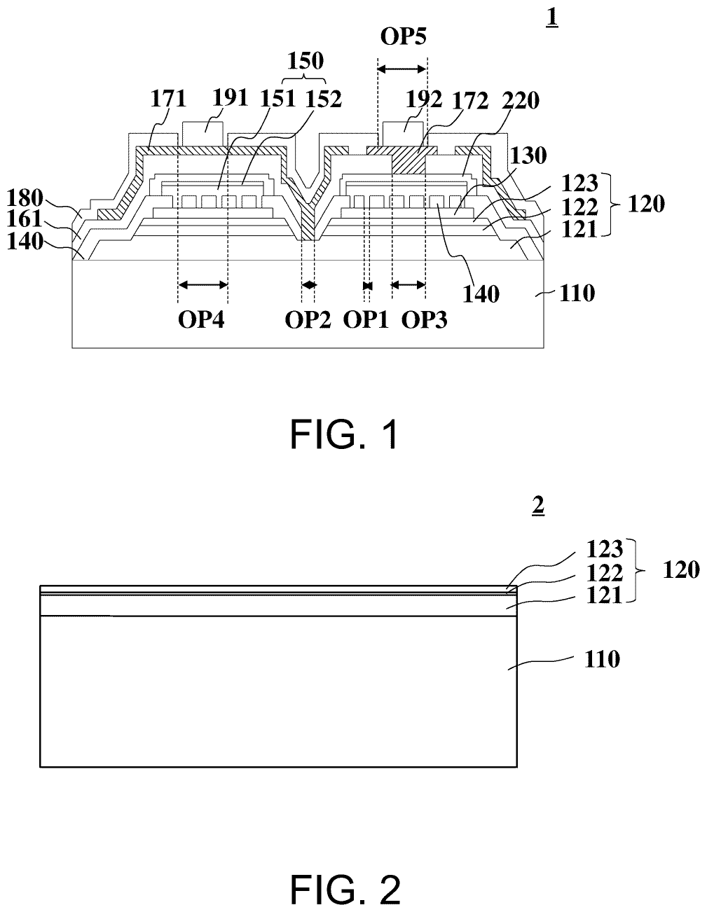

FIG. 1 is a cross-sectional view of a light emitting diode 1 disclosed in a first embodiment of the disclosure.

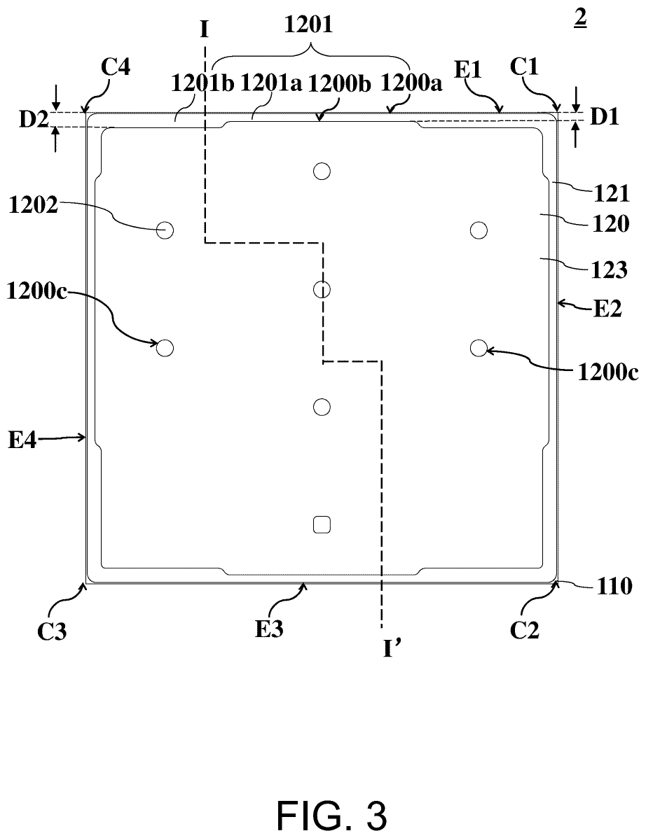

FIGS. 2 to 29 are schematic structural diagrams showing the steps of the manufacturing method of a light emitting diode 2 disclosed in a second embodiment of the disclosure.

FIG. 30 is a top view of a light emitting diode 3 disclosed in a third embodiment of the disclosure.

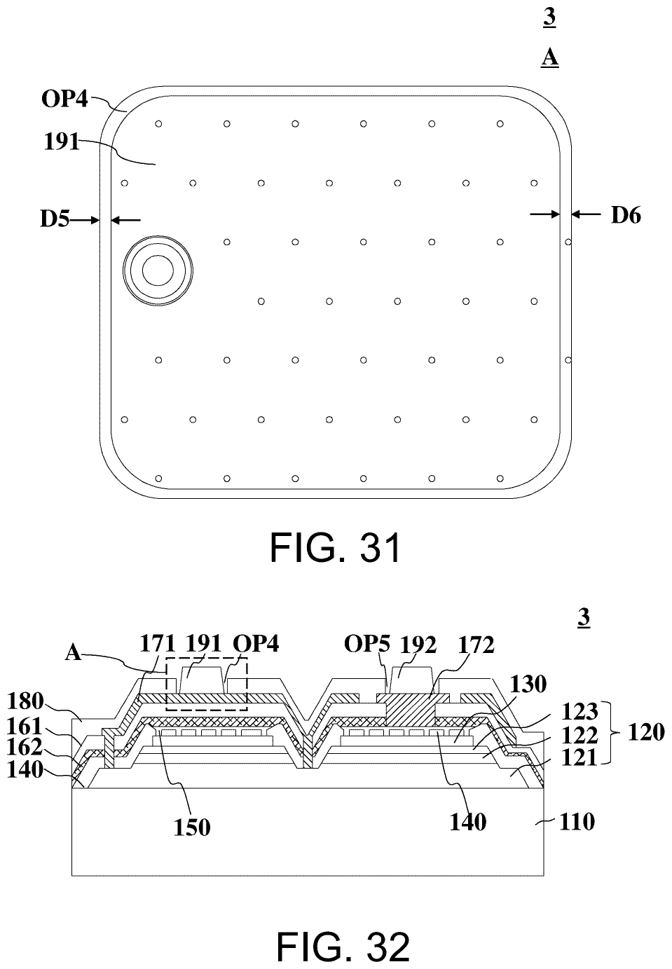

FIG. 31 is a partially enlarged schematic diagram of the light emitting diode 3 disclosed in FIG. 30.

FIG. 32 is a cross-sectional view of the light emitting diode 3 along the segment I-I′ disclosed in FIG. 30.

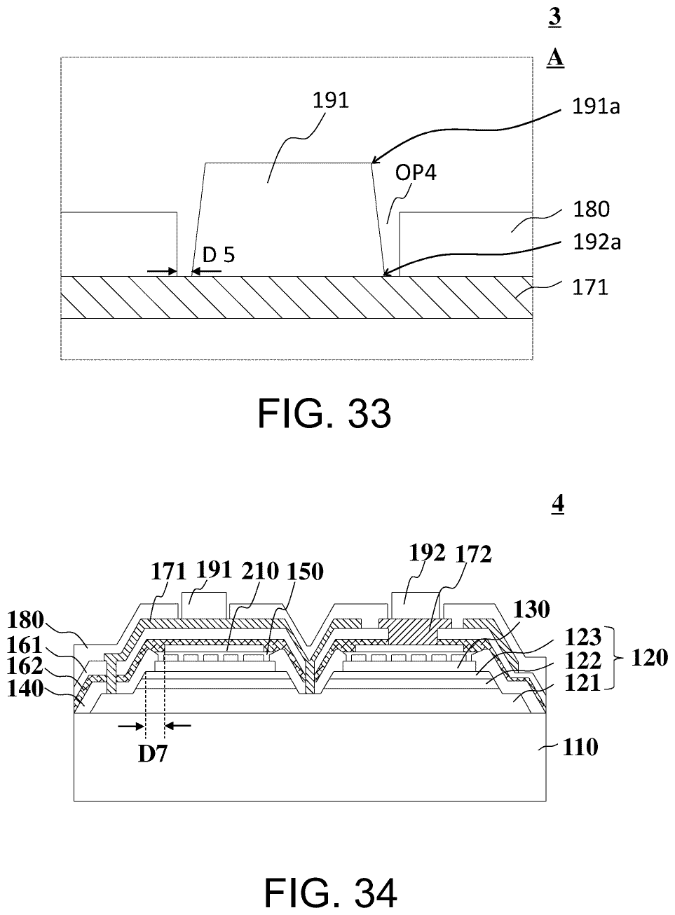

FIG. 33 is a partially enlarged schematic diagram of the light emitting diode 3 disclosed in FIG. 32.

FIG. 34 is a cross-sectional view of a light emitting diode 4 disclosed in a fourth embodiment of the disclosure.

### DESCRIPTION OF EMBODIMENTS

### Implementation Methods of the Invention

To make the objectives, technical solutions, and advantages of the embodiments of the disclosure clearer, the technical solutions in the embodiments of the disclosure will be clearly and completely described below in conjunction with the drawings in the embodiments of the disclosure. It is evident that the described embodiments are part of the embodiments of the disclosure rather than all of the embodiments. The technical features designed in the different embodiments of the disclosure described below may be combined with each other as long as there is no conflict. Based on the embodiments of the disclosure, all other embodiments obtained by a person having ordinary skill in the art without making creative efforts fall within the protection scope of the disclosure.

In the description of the disclosure, it should be noted that all terms (including technical terms and scientific terms) used in the disclosure have the same meanings as those commonly understood by a person having ordinary skill in the technical field of the disclosure and should not be interpreted as limitations to the disclosure. It should be further understood that the terms used in the disclosure should be understood as having meanings consistent with the meanings of these terms in the context of the specification and related technical fields, and should not be understood in an idealized or overly formal sense unless explicitly defined as such in the disclosure.

### First Embodiment

FIG. 1 is a cross-sectional view of a light emitting diode 1 disclosed in a first embodiment of the disclosure.

As shown in FIG. 1, the light emitting diode 1 includes a substrate 110 and a semiconductor stack 120 formed on the substrate 110. The semiconductor stack 120 includes a first semiconductor layer 121, a second semiconductor layer 123, and an active layer 122 located between the first semiconductor layer 121 and the second semiconductor layer 123.

In an embodiment of the disclosure, the substrate 110 may be formed using a carrier wafer suitable for semiconductor material growth. Additionally, the substrate 110 may be formed from a material with excellent thermal conductivity or may be a conductive substrate or an insulating substrate. Furthermore, the substrate 110 may be formed from a light-transmitting material and may have mechanical strength that does not cause bending of the entire semiconductor stack 120 and enables effective division into separate chips through a scribing and breaking process. For example, the substrate 110 may use a sapphire (Al₂O₃) substrate, a silicon carbide (SiC) substrate, a silicon (Si) substrate, a zinc oxide (ZnO) substrate, a gallium nitride (GaN) substrate, a gallium arsenide (GaA s) substrate, or a gallium phosphide (GaP) substrate. In particular, a sapphire (Al₂O₃) substrate is preferably used. In this embodiment, the substrate 110 is a sapphire substrate with a surface having a series of protrusions, including, for example, protrusions without a fixed slope formed by dry etching or protrusions with a certain slope formed by wet etching.

In an embodiment of the disclosure, a semiconductor stack 120 with optoelectronic properties, such as a light-emitting stack, is formed on the substrate 110 by metal-organic chemical vapor deposition (MOCVD), molecular beam epitaxy (MBE), hydride vapor phase epitaxy (HV PE), physical vapor deposition (PV D), or ion plating. The physical vapor deposition method includes sputtering or evaporation. The first semiconductor layer 121, the active layer 122, and the second semiconductor layer 123 may be formed from a group III nitride-based compound semiconductor, such as GaN, AlN, InGaN, AlGaN, InAlGaN, or at least one of these compounds. The first semiconductor layer 121 is a layer that supplies electrons and may be formed by injecting an n-type dopant, such as Si, Ge, Se, Te, or C. The second semiconductor layer 123 is a layer that supplies holes and may be formed by injecting a p-type dopant, such as Mg, Zn, Be, Ca, Sr, or Ba. The active layer 122 is a layer where the electrons supplied by the first semiconductor layer 121 recombine with the holes supplied by the second semiconductor layer 123 to emit light of a predetermined wavelength. The active layer 122 may be formed from a multilayer semiconductor thin film having a single-layer or multilayer quantum well structure in which well layers and barrier layers are alternately stacked. The composition or ratio of materials used in the active layer 122 may vary depending on the output light wavelength. For example, the emission wavelength of the light emitting diode 1 in the embodiment of the disclosure is between 420 nm and 580 nm. The active layer 122 may be formed as a structure comprising a well layer and a barrier layer using at least one of group III to group V compound semiconductor materials, such as InGaN/GaN, InGaN/InGaN, GaN/AlGaN, InAlGaN/GaN, GaAs(InGaAs)/AlGaAs, or GaP(InGaP)/AlGaP. However, the disclosure is not limited thereto. The well layer may be formed from a material having a smaller bandgap than the barrier layer.

In an embodiment of the disclosure, the light emitting diode 1 includes a transparent conductive layer 130. The transparent conductive layer 130 is formed on the semiconductor stack 120 and contacts the second semiconductor layer 123. The transparent conductive layer 130 may be in substantial contact with almost the entire upper surface of the second semiconductor layer 123. In this structure, when current is supplied to the light emitting diode, it may spread along the horizontal direction through the transparent conductive layer 130 and thus be uniformly supplied to the entire second semiconductor layer 123. In a preferred embodiment, the thickness of the transparent conductive layer 130 is in a range of 5 nm to 60 nm. When the thickness is less than 5 nm, the forward voltage (Vf) of the light emitting diode is likely to increase. When the thickness exceeds 60 nm, the light absorption effect significantly increases. The more preferable thickness of the transparent conductive layer 130 is in a range of 10 nm to 30 nm, for example, 15 nm or 20 nm. The material of the transparent conductive layer 130 may be ITO, InO, SnO, CTO, ATO, ZnO, GaP, or a combination thereof. The transparent conductive layer 130 may be formed by evaporation or sputtering.

In another embodiment (not shown in the figures), the transparent conductive layer 130 is provided with multiple opening portions that expose a part of the second semiconductor layer 123. By controlling the size and density of the opening portions, the area proportion of the semiconductor stack 120 occupied by the transparent conductive layer 130 is greater than 50% and less than 95%. This ensures that the transparent conductive layer 130 has sufficient ohmic contact with the second semiconductor layer 123 while reducing the area of the transparent conductive layer 130, thereby improving the brightness of the light emitting diode. Preferably, the area proportion of the semiconductor stack 120 occupied by the transparent conductive layer 130 is in a range of 70% to 90%. Specifically, the opening portions are arranged in an array and have a diameter in a range of 2 μm to 50 μm. The spacing between adjacent first opening portions OP1 is in a range of 1 μm to 20 μm. In this embodiment, the diameter of the opening portions is selected to be in a range of 2 μm to 10 μm, and the spacing is in a range of 5 μm to 20 μm.

In an embodiment of the disclosure, the light emitting diode 1 includes a first insulating layer 140. The first insulating layer 140 is formed on the semiconductor stack 120. The first insulating layer 140 includes one or more first opening portions OP1 to expose a part of the surface of the transparent conductive layer 130. The total cross-sectional area of the first opening portions OP1 accounts for 3% to 50% of the cross-sectional area ratio of the semiconductor stack 120, preferably 5% to 20%, and more preferably 10%. If the ratio is too low, the contact area between a reflective electrode layer 150 and the transparent conductive layer 130 through the first opening portions OP1 will be too small, making it difficult to control voltage. If the ratio is too high, the reflection effect of the structure formed by the transparent conductive layer 130, the first insulating layer 140 (such as a low refractive index material), and the reflective electrode layer 150 as an omnidirectional reflective layer structure will be affected.

The first insulating layer 140 may include at least one of SiO₂, SiN, SiOₓN_{y}, TiO₂, Si₃N₄, Al₂O₃, TiN, AlN, ZrO₂, TiAIN, TiSiN, HfO, TaO₂, and MgF₂. In an exemplary embodiment, the first insulating layer 140 may have a multilayer film structure in which insulating films with different refractive indices are alternately stacked and may be configured as a distributed Bragg reflector (DBR). The multilayer film structure may be a structure in which a first insulating film and a second insulating film, having a first refractive index and a second refractive index as different refractive indices, are alternately stacked.

In another exemplary embodiment, the first insulating layer 140 may be formed from a material with a refractive index lower than that of the second semiconductor layer 123. The first insulating layer 140, together with the reflective electrode layer 150 arranged to contact the upper portion of the first insulating layer 140, may constitute an omnidirectional reflector (ODR). In this way, the first insulating layer 140 may be used alone or in combination with the reflective electrode layer 150 as a reflective structure to increase the reflectivity of the light emitted from the active layer 122. Therefore, the light extraction efficiency may be significantly improved.

The thickness of the first insulating layer 140 may range from 100 nm to 1500 nm. Specifically, the thickness may range from 200 nm to 1000 nm. When the thickness of the first insulating layer 140 is less than 200 nm, the forward voltage is high, and the light output is low, making it undesirable. On the other hand, if the thickness of the first insulating layer 140 exceeds 1000 nm, the light output becomes saturated. Therefore, it is preferable that the thickness of the first insulating layer 140 does not exceed 1000 nm, and more specifically, it may be 900 nm or less.

In an embodiment of the disclosure, the light emitting diode 1 includes a reflective electrode layer 150. The reflective electrode layer 150 is formed on the semiconductor stack 120. The reflective electrode layer 150 contacts the transparent conductive layer 130 through the first opening portion OP1. The reflective electrode layer 150 comprises a metal reflective layer 151 and a metal protective layer 152. The metal reflective layer 151 is formed on the metal protective layer 152. The metal protective layer 152 may reduce the risk of oxidation of the metal reflective layer 151 in air or corrosion by etching solution during the fabrication process (e.g., during photoresist removal).

The metal reflective layer 151 includes a reflective metal with a high reflectivity for the light emitted by the light emitting diode, such as A g, Al, Rh, Ru, Ti, Cr, Ni, or an alloy or laminated structure of the above materials.

The material of the metal protective layer 152 may include nickel (Ni), chromium (Cr), platinum (Pt), titanium (Ti), tungsten (W), zinc (Zn), or an alloy or laminated structure of the above materials. In an embodiment, when the metal protective layer 152 is a metal laminate, the metal protective layer 152 is formed by alternately stacking two or more layers of metal, such as Cr/Pt, Cr/Ti, Cr/TiW, Cr/W, Cr/Zn, Ti/Pt, Ti/W, Ti/TiW, Ti/Zn, Pt/TiW, Pt/W, Pt/Zn, TiW/W, TiW/Zn, W/Zn, Ni/Pt, Ni/Ti, Ni/TiW, Ni/W, or Ni/Zn.

The light emitted by the semiconductor stack 120 may pass through the first insulating layer 140 and reach the surface of the reflective electrode layer 150, where it is reflected back by the reflective electrode layer 150. Therefore, the first insulating layer 140 has a certain degree of light transmittance for the light emitted by the active layer. More preferably, according to the principle of light reflection, the first insulating layer 140 has a lower refractive index than the material of the semiconductor stack 120, allowing small-angle light emitted by the active layer 122 to be transmitted or refracted to the first reflective layer 130. Incident light exceeding the total reflection angle is completely reflected back. Therefore, relying on the combination of the first insulating layer 140 and the reflective electrode layer 150, the light reflection effect is higher than that of the reflective electrode layer 150 alone.

Since the metal protective layer 152 formed on the metal reflective layer 151 has a relatively thin thickness, it provides effective protection against electromigration and thermal diffusion of the metal reflective layer 151. In an embodiment of the disclosure, the light emitting diode 1 includes a metal barrier layer 220. The metal barrier layer 220 is formed on the reflective electrode layer 150, and an edge of the metal barrier layer 220 is located on the upper surface of a second insulating layer 161. The metal barrier layer 220 covers the reflective electrode layer 150 to prevent electromigration or thermal diffusion of the metal contained in the reflective electrode layer 150. To effectively protect the reflective electrode layer 150, the metal barrier layer 220 needs to have sufficient thickness, especially at the edge of the reflective electrode layer 150. Therefore, a thickness between the edge of the metal barrier layer 220 and the edge of the reflective electrode layer 150 is greater than 4 μm. To provide sufficient space for forming the metal barrier layer 220 between the reflective electrode layer 150 and the semiconductor stack 120, a spacing between the reflective electrode layer 150 and the semiconductor stack 120 is greater than 8 μm. This ensures that leakage and electrostatic discharge (ESD) abnormalities do not occur during the chip fabrication process.

In an embodiment of the disclosure, the thickness of the metal reflective layer 151 is in a range of 100 nm to 200 nm, the thickness of the metal protective layer 152 is in a range of 100 nm to 500 nm, and the thickness of the metal barrier layer 220 is in a range of 500 nm to 1500 nm.

The metal barrier layer 220 may include a metal such as titanium (Ti), tungsten (W), aluminum (Al), indium (In), tin (Sn), nickel (Ni), platinum (Pt), chromium (Cr), gold (Au), or titanium tungsten (TiW), or an alloy of the above materials. The metal barrier layer 220 may be a single-layer or laminated structure. The laminated structure may include, for example, titanium (Ti)/aluminum (Al) and/or titanium (Ti)/tungsten (W).

In an embodiment of the disclosure, the light emitting diode 1 includes a second insulating layer 161. The second insulating layer 161 is formed on the metal barrier layer 220 and includes a second opening portion OP2 that partially exposes the first semiconductor layer 121 and a third opening portion OP3 that partially exposes the metal barrier layer 220.

The second insulating layer 161 may include an insulating material prepared using physical vapor deposition or chemical vapor deposition, such as silicon nitride (SiNₓ), silicon oxide (SiOₓ), titanium oxide (TiOₓ), or magnesium fluoride (MgF₂). Additionally, the second insulating layer 161 may be composed of multiple layers and may include a distributed Bragg reflector in which insulating materials with different refractive indices are alternately stacked. The second insulating layer 161 includes the structure of the distributed Bragg reflector, which re-reflects the light that is not reflected by the omnidirectional reflector, thereby improving the luminous efficiency of the light emitting device.

In an embodiment of the disclosure, the light emitting diode 1 includes a first connecting electrode 171 and a second connecting electrode 172. The first connecting electrode 171 contacts the first semiconductor layer 121 through the second opening portion OP2 and extends to cover the surface of the second insulating layer 161. The first connecting electrode 171 is insulated from the second semiconductor layer 123 by the second insulating layer 161. The second connecting electrode 172 contacts the metal barrier layer 220 through the third opening portion OP3 and extends to cover the surface of the second insulating layer 161. The second connecting electrode 172 is electrically connected to the second semiconductor layer 123 through the metal barrier layer 220.

In an embodiment of the disclosure, the light emitting diode 1 includes a third insulating layer 180. The third insulating layer 180 is formed on the semiconductor stack 120 and covers the first connecting electrode 171 and the second connecting electrode 172. The third insulating layer 180 includes a fourth opening portion OP4 that exposes a part of the surface of the first connecting electrode 171 and a fifth opening portion OP5 that exposes a part of the surface of the second connecting electrode 172.

The third insulating layer 180 may include SiO₂, SiN, and the like. The third insulating layer 180 may have a multilayer film structure formed by alternately stacking high-refractive-index dielectric films and low-refractive-index dielectric films, such as a Bragg reflector (DBR).

The material of the high-refractive-index dielectric film may include TiO₂, Nb₂Os, Ta₂Os, HfO₂, or ZrO₂. The material of the low-refractive-index dielectric film may include SiO₂, MgF₂, or SiON. The thickness of the third insulating layer 180 is between 500 nm and 1500 nm. The total area of multiple fourth opening portions OP4 and multiple fifth opening portions OP5 in the third insulating layer 180 is preferably greater than 20% of the total area of the semiconductor stack 120.

In an embodiment of the disclosure, the light emitting diode 1 includes a first pad electrode 191 and a second pad electrode 192. The first pad electrode 191 contacts the first connecting electrode 171 through the fourth opening portion OP4 and is electrically connected to the first semiconductor layer 121 through the first connecting electrode 171. The second pad electrode 192 contacts the second connecting electrode 172 through the fifth opening portion OP5 and is electrically connected to the second semiconductor layer 123 through the second connecting electrode 172.

In an embodiment of the disclosure, each of the first pad electrode 191 and the second pad electrode 192 may include a single film made of a single material selected from a group consisting of gold (Au), tin (Sn), nickel (Ni), lead (Pb), silver (Ag), indium (In), chromium (Cr), germanium (Ge), silicon (Si), titanium (Ti), tungsten (W), and platinum (Pt), or an alloy composed of at least two of these materials, or a multilayer structure that includes a combination thereof.

Each of the first pad electrode 191 and the second pad electrode 192 may be used as an external terminal of the light emitting diode. However, the concept of the disclosure is not limited thereto.

### Second Embodiment

FIGS. 2 to 29 are schematic structural diagrams showing the steps of the manufacturing method of a light emitting diode 2 disclosed in a second embodiment of the disclosure.

The light emitting diode 2 has a substantially similar structure to the light emitting diode 1. Therefore, for the structures of the light emitting diode 2 in FIGS. 2 to 29 that have the same names and reference numerals as those of the light emitting diode 1 in FIG. 2, they represent the same structures, have the same materials, or have the same functions. Accordingly, descriptions will be appropriately omitted or not repeated here.

As shown in FIG. 2, the manufacturing method of the light emitting diode 2 includes a step of forming a semiconductor stack 120. This step includes providing a substrate 110 and forming the semiconductor stack 120 on the substrate 110, wherein the semiconductor stack 120 includes a first semiconductor layer 121, a second semiconductor layer 123, and an active layer 122 located between the first semiconductor layer 121 and the second semiconductor layer 123.

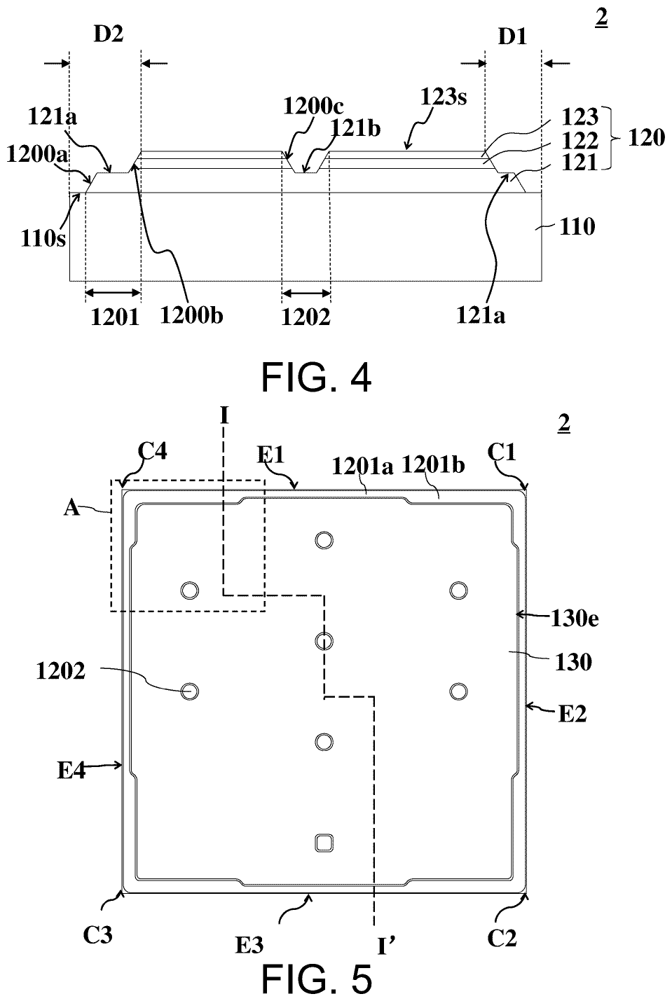

As shown in FIG. 3 and FIG. 4, wherein FIG. 4 is the cross-sectional view along segment I-I′ in the top view FIG. 3, after the semiconductor stack 120 is formed on the substrate 110, the manufacturing method of the light emitting diode 2 includes a mesa formation step. The semiconductor stack 120 is patterned by photolithography and etching to form a first mesa 1201 and multiple second mesas 1202. Through photolithography and etching processes, an internal portion of the second semiconductor layer 123 and the active layer 122 is removed to form multiple second mesas 1202. The multiple second mesas 1202 correspondingly expose a second surface 121b of the first semiconductor layer 121. Here, each second mesa 1202 is defined by an inner sidewall 1200c and the second surface 121b. One end of the inner sidewall 1200c is connected to the second surface 121b of the first semiconductor layer 121, and the other end of the inner sidewall 1200c is connected to a surface 123s of the second semiconductor layer 123. In the same or another photolithography and etching process, portions of the second semiconductor layer 123 and the active layer 122 surrounding the semiconductor stack 120 are removed to form the first mesa 1201. The first mesa 1201 exposes a first surface 121a of the first semiconductor layer 121. In another embodiment, during the photolithography and etching process, a part of the first semiconductor layer 121 is further etched to a greater depth to expose the first surface 121a. Here, the first mesa 1201 is defined by a first outer sidewall 1200a, a second outer sidewall 1200b, and the first surface 121a. One end of the first outer sidewall 1200a is connected to the first surface 121a of the first mesa 1201, and the other end is connected to an exposed surface 110s of the substrate 110. One end of the second outer sidewall 1200b is connected to the first surface 121a of the first mesa 1201, and the other end is connected to the surface 123s of the second semiconductor layer 123. The first outer sidewall 1200a and the second outer sidewall 1200b may be inclined relative to the first surface 121a. The first mesa 1201 is formed along a periphery of the semiconductor stack 120 and is located at and/or surrounds an edge of one or more semiconductor stacks 120. In an embodiment, the first outer sidewall 1200a is inclined relative to the exposed surface 110s of the substrate 110. An acute angle is formed between the first outer sidewall 1200a and the exposed surface 110s of the substrate 110. In another embodiment, an obtuse angle is formed between the first outer sidewall 1200a and the exposed surface 110s of the substrate 110 (not shown in the figures).

In an embodiment of the disclosure, as shown in FIG. 3, the second mesa 1202 is located inside the semiconductor stack 120 and exposes the second surface 121b of the first semiconductor layer 121. The shape of the second mesa 1202 may include an elliptical shape, a circular shape, a rectangular shape, or any other arbitrary shape. The second mesa 1202 may be regularly arranged on the semiconductor stack 120. However, it should be understood that the disclosure is not limited thereto, and the arrangement and number of second mesas 1202 may be varied in different ways.

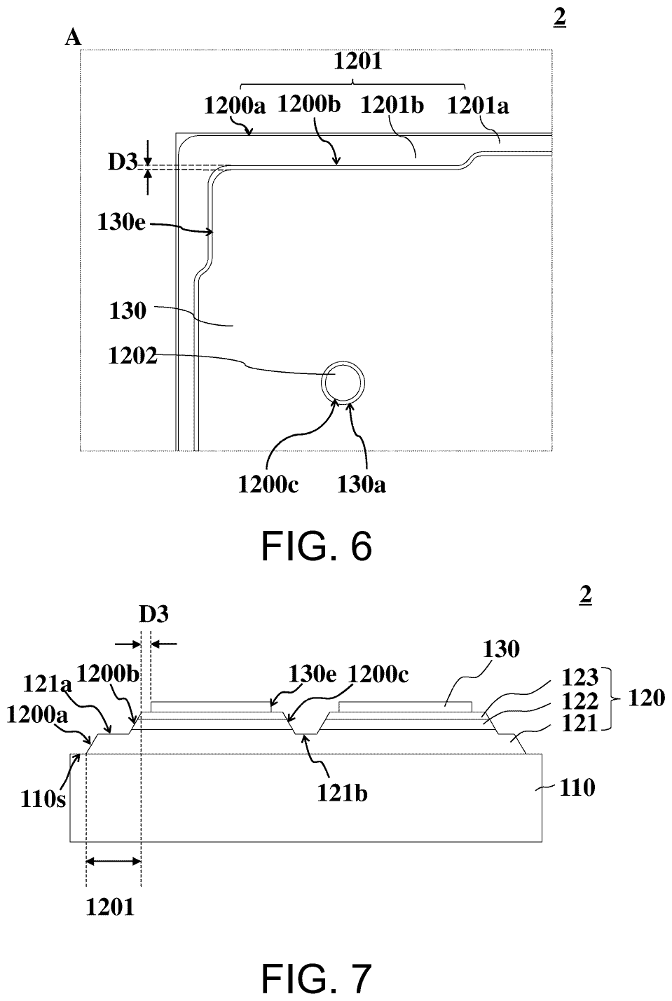

Following the mesa formation step, as shown in FIGS. 5-7, wherein FIG. 6 is the partially enlarged schematic diagram of the top view FIG. 5 and FIG. 7 is the cross-sectional view along segment I-I′ in FIG. 5, the manufacturing method of the light emitting diode includes a transparent conductive layer formation step. A transparent conductive layer 130 is formed on the semiconductor stack 120 by a physical vapor deposition method or a chemical vapor deposition method, and the transparent conductive layer 130 contacts the second semiconductor layer 123. In some embodiments, a horizontal distance between a sidewall 130e of the transparent conductive layer 130 and the second outer sidewall 1200b or the inner sidewall 1200c of the semiconductor stack 120 is a third distance D3. The third distance D3 may be less than 10 μm and is preferably in a range of 2 μm to 6 μm. In this structure, when current is supplied to the light emitting diode, it may spread along the horizontal direction through the transparent conductive layer 130 and thus be uniformly supplied to the entire second semiconductor layer 123. If the third distance D3 is greater than 10 μm, the contact area between the transparent conductive layer 130 and the second semiconductor layer 123 becomes too small, causing the voltage of the light emitting diode to be too high and the current diffusion effect to be poor.

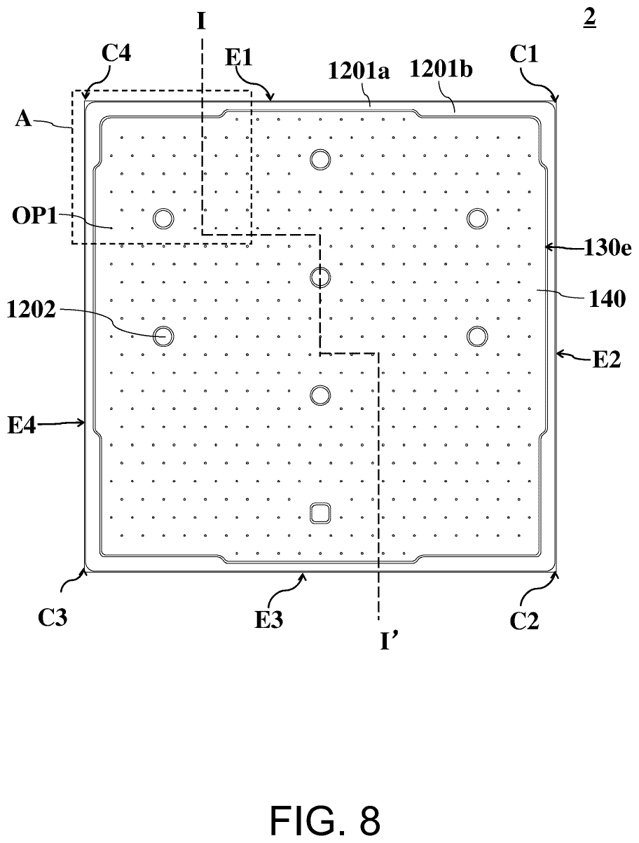

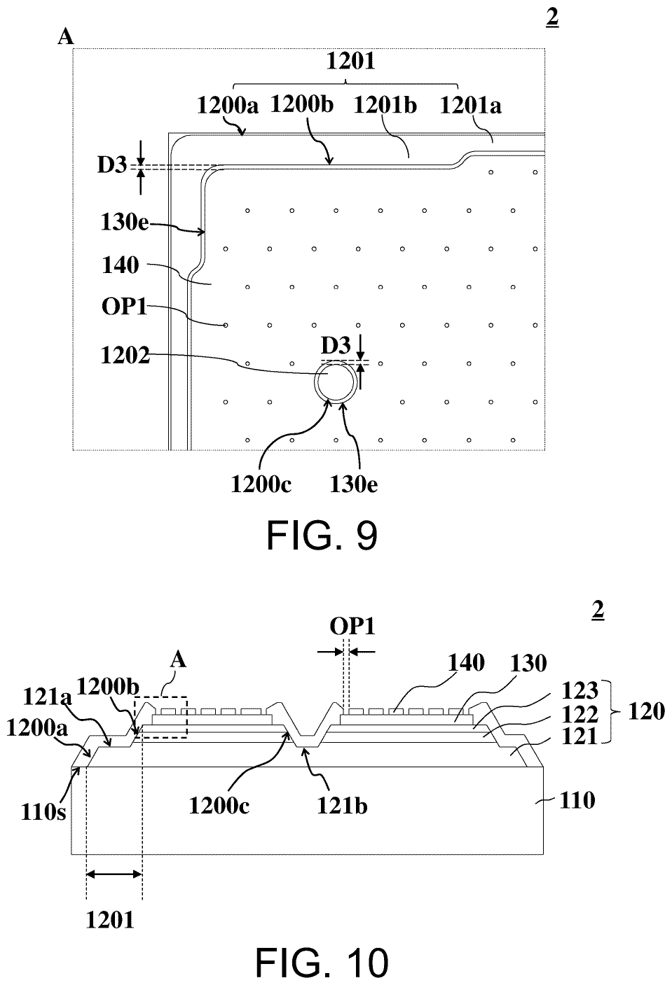

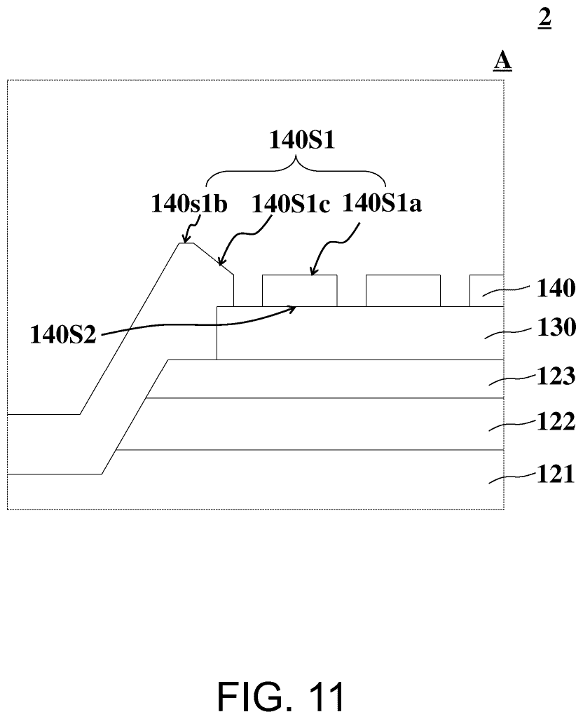

In an embodiment of the disclosure, following the transparent conductive layer formation step, as shown in FIGS. 8-11, wherein FIG. 9 is the partially enlarged schematic diagram of the top view FIG. 8, FIG. 10 is the cross-sectional view along segment I-I′ in FIG. 8, and FIG. 11 is the partially enlarged schematic diagram of FIG. 8, the manufacturing method of the light emitting diode 2 includes a first insulating layer formation step. A first insulating layer 140 is formed on the semiconductor stack 120 by a physical vapor deposition method or a chemical vapor deposition method. The first insulating layer 140 is then patterned through photolithography and etching. The first insulating layer 140 may include one or more first opening portions OP1 to expose a part of the surface of the transparent conductive layer 130. The first insulating layer 140 is formed on the transparent conductive layer 130 and wraps around the sidewall 130e of the transparent conductive layer 130 as well as the sidewalls of the semiconductor stack 120. Specifically, the first insulating layer 140 may cover a part of the surface of the transparent conductive layer 130, the second outer sidewall 1200b of the semiconductor stack 120, the first surface 121a of the first semiconductor layer 121, the first outer sidewall 1200a, the inner sidewall 1200c, and the second surface 121b of the first semiconductor layer 121. When the mesa has inclined sidewalls, the first insulating layer 140 formed on the mesa sidewalls may be more stably deposited.

In an embodiment, as shown in FIG. 11, the first insulating layer 140 includes an upper surface 140S1 away from the semiconductor stack 120 and a lower surface 140S2 opposite to the upper surface 140S1. The upper surface 140S1 includes a first surface 140S1a, a second surface 140S1b, and a third surface 140S1c that connects the first surface 140S1a and the second surface 140S1b. A thickness between the first surface 140S1a and the lower surface 140S2 is smaller than a thickness between the second surface 140S1b and the lower surface 140S2. That is, the first surface 140S1a is closer to the semiconductor stack 120 than the second surface 140S1b. The third surface 140S1c is an inclined surface relative to the first surface 140S1a and the second surface 140S1b. An obtuse angle is formed between the third surface 140S1c and the first surface 140S1a.

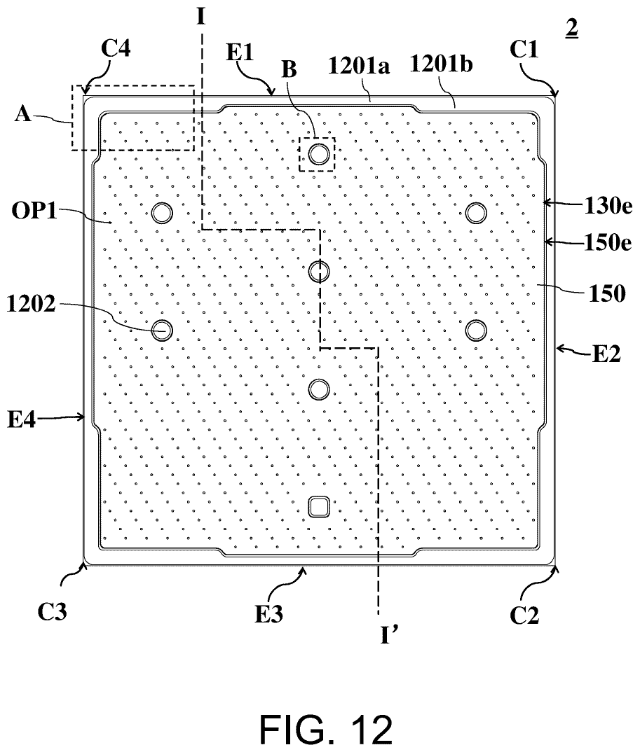

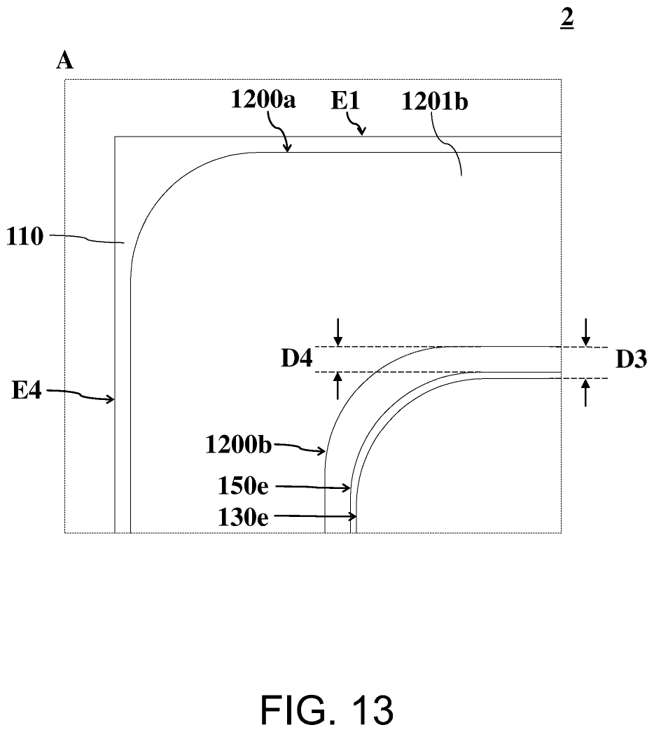

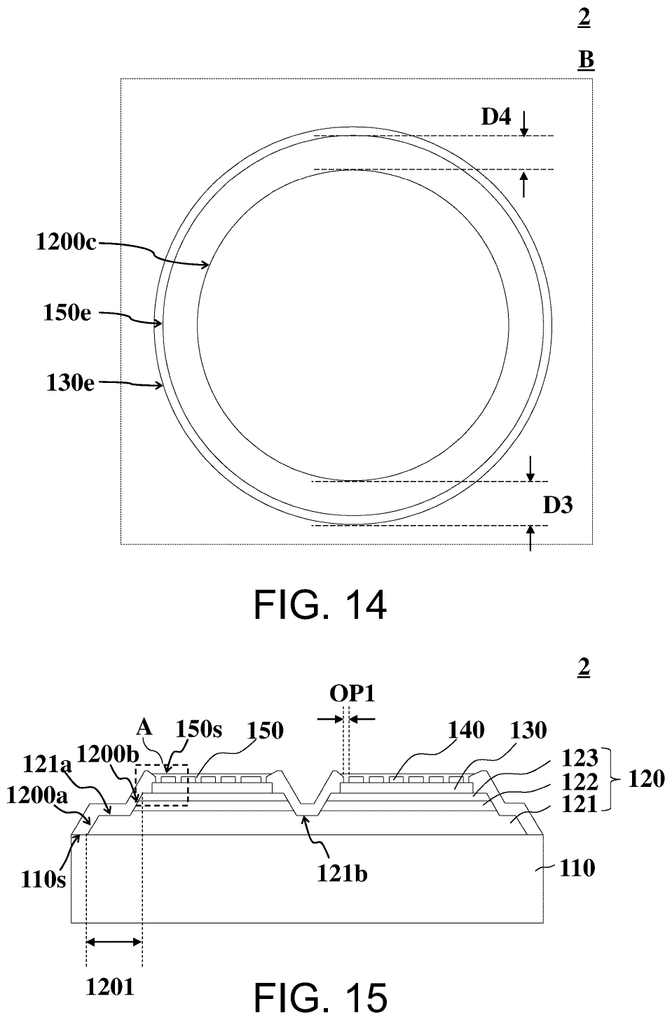

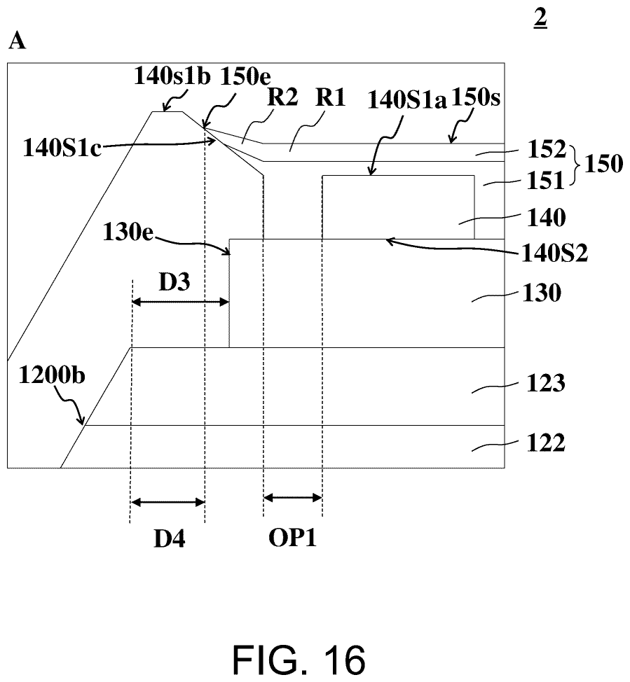

Following the first insulating layer 140 formation step, as shown in FIGS. 12-16, wherein FIG. 13 is the partially enlarged schematic diagram of region A in the top view FIG. 12, FIG. 14 is the partially enlarged schematic diagram of region B in FIG. 12, FIG. 15 is the cross-sectional view along segment I-I′ in FIG. 12, and FIG. 16 is the partially enlarged schematic diagram of FIG. 12, the manufacturing method of the light emitting diode includes a reflective electrode layer formation step. The reflective electrode layer 150 is directly formed on the semiconductor stack 120 by a physical vapor deposition method or magnetron sputtering. The reflective electrode layer 150 is disposed on the first surface 140S1a and the third surface 140S1c of the first insulating layer 140 and contacts the transparent conductive layer 130 through the first opening portion OP1. An edge 150e of the reflective electrode layer 150 is formed on the third surface 140S1c of the first insulating layer 140.

In an embodiment, as shown in FIG. 16, the reflective electrode layer 150 includes a metal reflective layer 151 and a metal protective layer 152. The metal reflective layer 151 is formed on the first surface 140S1a of the first insulating layer 140, and an edge of the metal reflective layer 151 is located on the third surface 140S1c. By controlling the formation of the edge of the metal reflective layer 151 on the third surface 140S1c, deposition of the metal protective layer 152 above the edge of the metal reflective layer 151 is facilitated.

The metal protective layer 152 may cover the upper surface and side surface of the metal reflective layer 151 to protect the metal reflective layer 151 from oxidation or corrosion during the fabrication process (e.g., photoresist removal) and to suppress the migration of metal elements contained in the metal reflective layer 151. The metal protective layer 152 may include an upper portion R1 covering the upper surface of the metal reflective layer 151 and a side portion R2 covering the side surface of the metal reflective layer 151. The side portion R2 is formed on the third surface 140S1c of the first insulating layer 140, and the thickness of the side portion R2 gradually decreases. For example, the upper portion R1 and the side portion R2 may contact each other and form a continuous structure.

In an embodiment, the thickness of the metal reflective layer 151 is in a range of 100 nm to 200 nm, and the thickness of the upper portion R1 of the metal protective layer 152 is in a range of 100 nm to 500 nm.

In an embodiment, as shown in FIG. 16, a thickness between a surface 150s of the reflective electrode layer 150 away from the semiconductor stack 120 and the lower surface 140S2 of the first insulating layer 140 is smaller than a thickness between the second surface 140S1b of the first insulating layer 140 and the lower surface 140S2. This ensures that the reflective electrode layer 150 has sufficient reflectivity while maintaining adhesion between the reflective electrode layer 150 and the first insulating layer 140.

In an embodiment of the disclosure, a horizontal distance between the edge 150e of the reflective electrode layer 150 and the second outer sidewall 1200b or the inner sidewall 1200c of the semiconductor stack 120 is a fourth distance D4 (i.e., the horizontal distance between the edge 150e of the reflective electrode layer 150 and the upper edge of the second semiconductor layer 123). The fourth distance D4 is in a range of 1 μm to 5 μm, for example, 2 μm, 3 μm, or 4 μm. Because the fourth distance D4 is relatively small, designing a metal barrier layer 220 as in the light emitting diode 1 may cause leakage and ESD abnormalities. Therefore, in an embodiment of the disclosure, the structure of the metal barrier layer 220 is removed from the reflective electrode layer 150 to maximize the area of the reflective electrode layer 150, thereby improving the brightness of the light emitting diode. If the fourth distance D4 is less than 1 μm, the spacing between the reflective electrode layer 150 and the semiconductor stack 120 is too small, which may lead to leakage and ESD abnormalities in the light emitting diode. If the fourth distance D4 is greater than 5 μm, the area of the reflective electrode layer 150 is reduced, thereby lowering the brightness of the light emitting diode.

In an embodiment of the disclosure, since the metal barrier layer 220 is removed in the light emitting diode 2, a projection of the transparent conductive layer 130 in the growth direction of the semiconductor stack 120 is located within a projection of the reflective electrode layer 150 in the growth direction of the semiconductor stack 120. This maximizes the area of the reflective electrode layer 150, ensuring that the third distance D3 is greater than the fourth distance D4. In an embodiment of the disclosure, as shown in FIGS. 15 and 16, a projection of the transparent conductive layer 130 in the growth direction of the semiconductor stack 120 is located within projections of the third surface 140S1c and the first surface 140S1a of the first insulating layer 140 in the growth direction of the semiconductor stack 120.

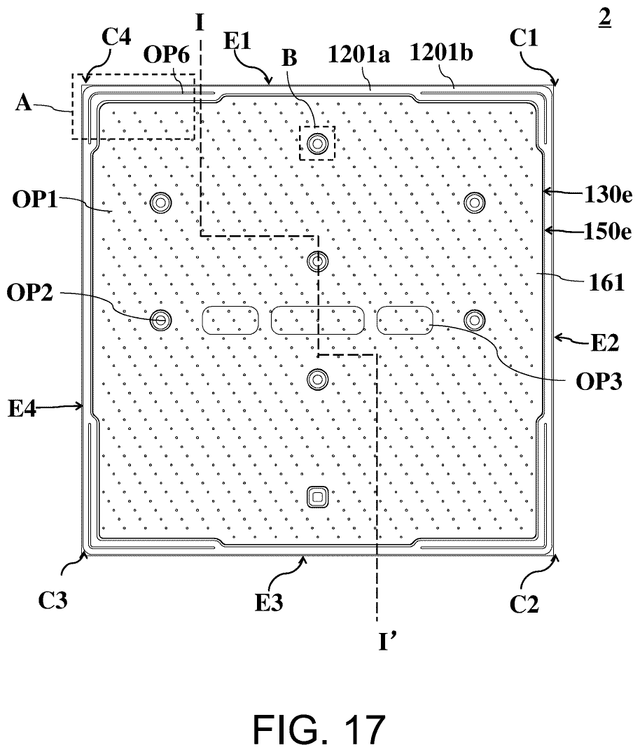

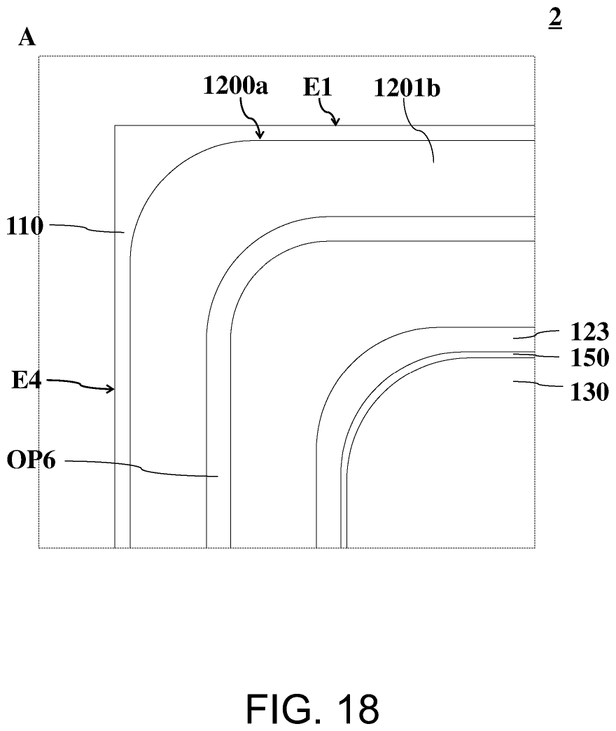

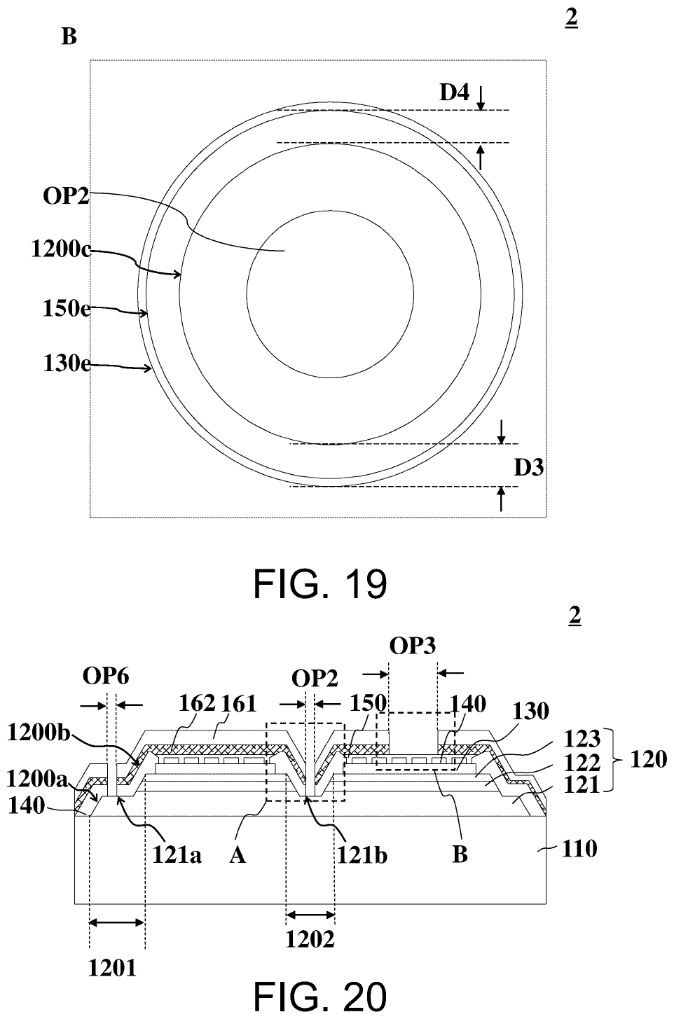

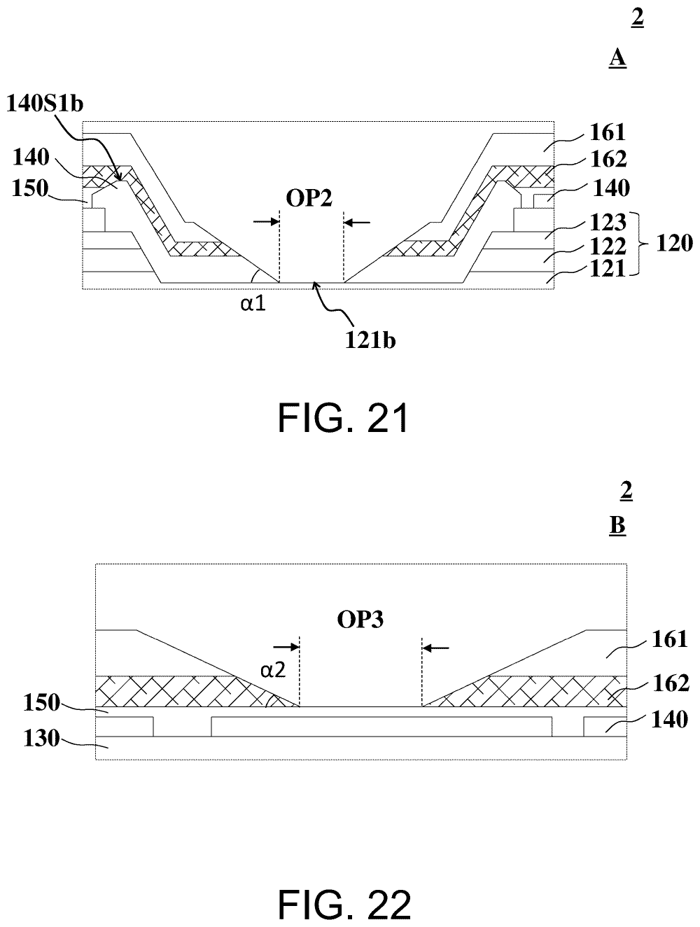

Following the reflective electrode layer 150 formation step, as shown in FIGS. 17-22, wherein FIG. 18 is the partially enlarged schematic diagram of region A in the top view FIG. 17, FIG. 19 is the partially enlarged schematic diagram of region B in FIG. 17, FIG. 20 is the cross-sectional view along segment I-I′ in FIG. 17, FIG. 21 is the partially enlarged schematic diagram of region A in FIG. 20, and FIG. 22 is the partially enlarged schematic diagram of region B in FIG. 20, the manufacturing method of the light emitting diode includes a step of forming a fourth insulating layer 162 and a second insulating layer 161. The fourth insulating layer 162 is formed on the semiconductor stack 120 by atomic layer deposition. The fourth insulating layer 162 is formed on the reflective electrode layer 150 and extends to the second surface 140S1b of the first insulating layer 140. The fourth insulating layer 162 may be aluminum oxide or silicon oxide, and aluminum oxide is preferred. The fourth insulating layer 162 prepared by atomic layer deposition has excellent density, which enhances the protection of the reflective electrode layer 150 and further prevents metal elements contained in the reflective electrode layer 150 from undergoing electromigration or thermal diffusion, thereby increasing the area of the reflective electrode layer 150 to enhance the brightness of the light emitting diode and preventing migration, so as to improve the reliability of the light emitting diode. In an embodiment, the second insulating layer 161 is formed on the fourth insulating layer 162 by a physical vapor deposition method, a chemical vapor deposition method, or other similar techniques. The second insulating layer 161 may include one or more of silicon oxide, silicon nitride, silicon oxynitride, or titanium oxide.

In an embodiment, the thickness of the fourth insulating layer 162 is in a range of 20 nm to 150 nm. If the thickness of the fourth insulating layer 162 is less than 20 nm, the protective effect of the fourth insulating layer 162 on the reflective electrode layer 150 is limited and cannot effectively prevent metal elements contained in the reflective electrode layer 150 from undergoing electromigration or thermal diffusion. If the thickness of the fourth insulating layer 162 is greater than 150 nm, the fabrication process takes too long, leading to reduced efficiency and increased cost. The thickness of the second insulating layer 161 is in a range of 20 nm to 150 nm. In a preferred embodiment, the thickness of the second insulating layer 161 is greater than the thickness of the fourth insulating layer 162. This takes advantage of the strong coverage and high blocking ability of the film layer formed by atomic layer deposition while also ensuring production efficiency.

The fourth insulating layer 162 and the second insulating layer 161 are patterned through photolithography or etching to form a second opening portion OP2, which exposes the second surface 121b of the first semiconductor layer 121, and a third opening portion OP3, which exposes a part of the surface of the reflective electrode layer 150. During the patterning process of the fourth insulating layer 162 and the second insulating layer 161, the part of the first insulating layer 140 covering the mesa, which was formed in the previous first insulating layer 140 formation step, is partially etched and removed to expose the second surface 121b of the first semiconductor layer 121.

In an embodiment of the disclosure, to increase the contact area between the first connecting electrode 171 and the first semiconductor layer 121 through the second opening portion OP2 and thereby reduce the voltage of the light emitting diode, the second opening portion OP2 may be formed using inductively coupled plasma (ICP) dry etching. Since the metal protective layer 152 in the reflective electrode layer 150 is relatively thin, if the third opening portion OP3 is formed using ICP dry etching, the gases used in ICP dry etching may corrode the metal protective layer 152, causing electromigration or thermal diffusion of Ag or Al in the metal reflective layer 151. Therefore, in an embodiment of the disclosure, the third opening portion OP3 is formed using wet etching.

As shown in FIG. 21, a first included angle α1 may be formed between the sidewall of the second opening portion OP2 and the second surface 121b of the first semiconductor layer 121. As shown in FIG. 22, a second included angle α2 may be formed between the sidewall of the third opening portion OP3 and the surface of the reflective electrode layer 150.

In an embodiment of the disclosure, since the second opening portion OP2 is formed using ICP dry etching and the third opening portion OP3 is formed using BOE wet etching, the first included angle α1 may be greater than the second included angle α2.

In another embodiment of the disclosure, since a metal layer 210 is formed on the reflective electrode layer 150, it may prevent the gases used in ICP dry etching from corroding the reflective electrode layer 150. Therefore, the third opening portion OP3 may be formed using ICP dry etching. As a result, the first included angle α1 may be equal to the second included angle α2.

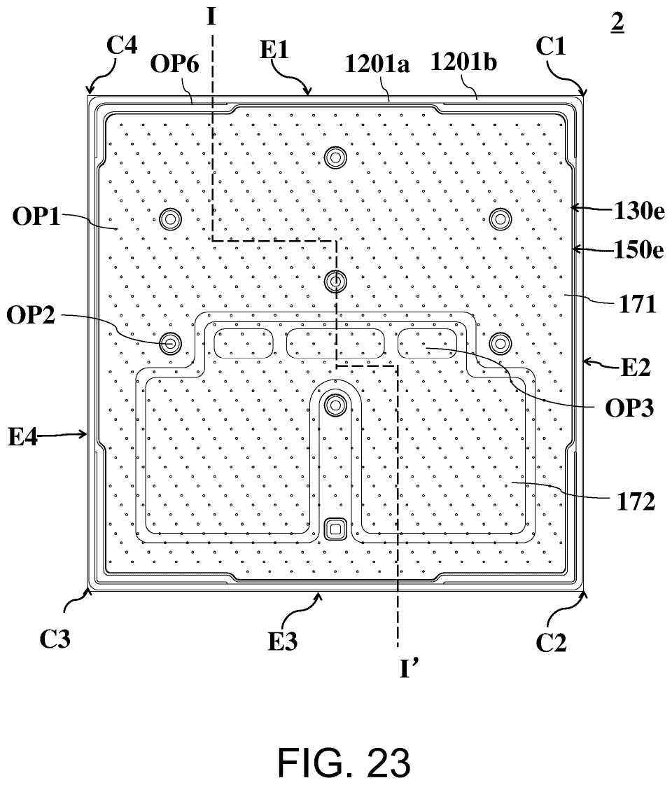

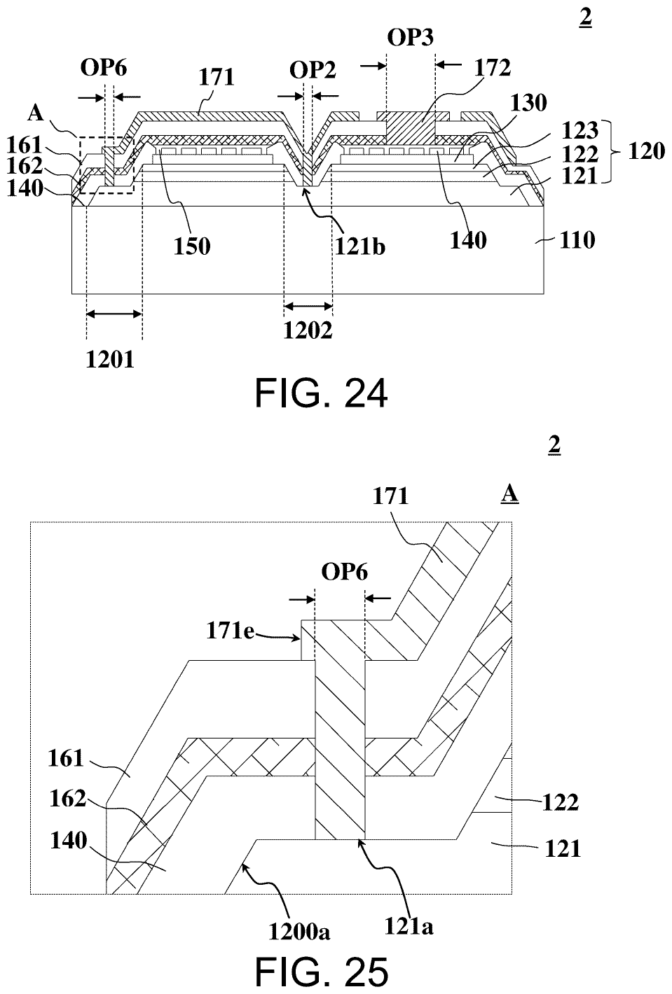

Following the fourth insulating layer 162 and second insulating layer 161 formation step, as shown in FIGS. 23-25, wherein FIG. 24 is the cross-sectional view along segment I-I′ in the top view FIG. 23, and FIG. 25 is the partially enlarged schematic diagram of region A in FIG. 24, the manufacturing method of the light emitting diode includes a step of forming connecting electrodes 170. The connecting electrodes 170 are formed on the semiconductor stack 120 by a physical vapor deposition method, magnetron sputtering, or similar techniques. The connecting electrodes 170 are then patterned through photolithography and etching to form a first connecting electrode 171 and a second connecting electrode 172.

The first connecting electrode 171 contacts the second surface 121b of the first semiconductor layer 121 through the second opening portion OP2 and extends to cover the surface of the second insulating layer 161. The first connecting electrode 171 is insulated from the second semiconductor layer 123 by the second insulating layer 161. The second connecting electrode 172 contacts the reflective electrode layer 150 through the third opening portion OP3 and extends to cover the surface of the second insulating layer 161. The second connecting electrode 172 is electrically connected to the second semiconductor layer 123 through the reflective electrode layer 150.

In an embodiment of the disclosure, the first connecting electrode 171 and the second connecting electrode 172 are spaced apart from each other at a distance, such that the first connecting electrode 171 does not contact the second connecting electrode 172. In the top view of the light emitting diode, the first connecting electrode 171 surrounds multiple sidewalls of the second connecting electrode 172. To facilitate better current diffusion, the area of the first connecting electrode 171 is greater than the area of the second connecting electrode 172.

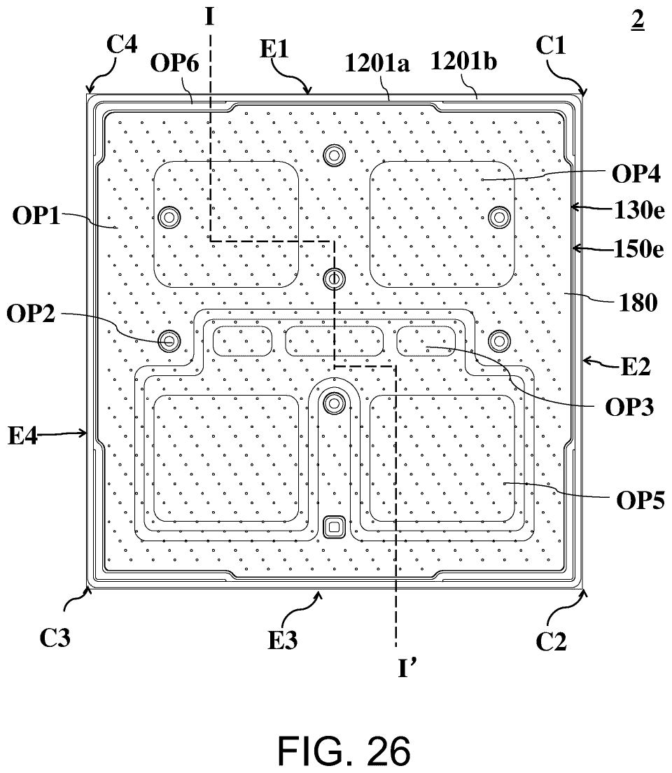

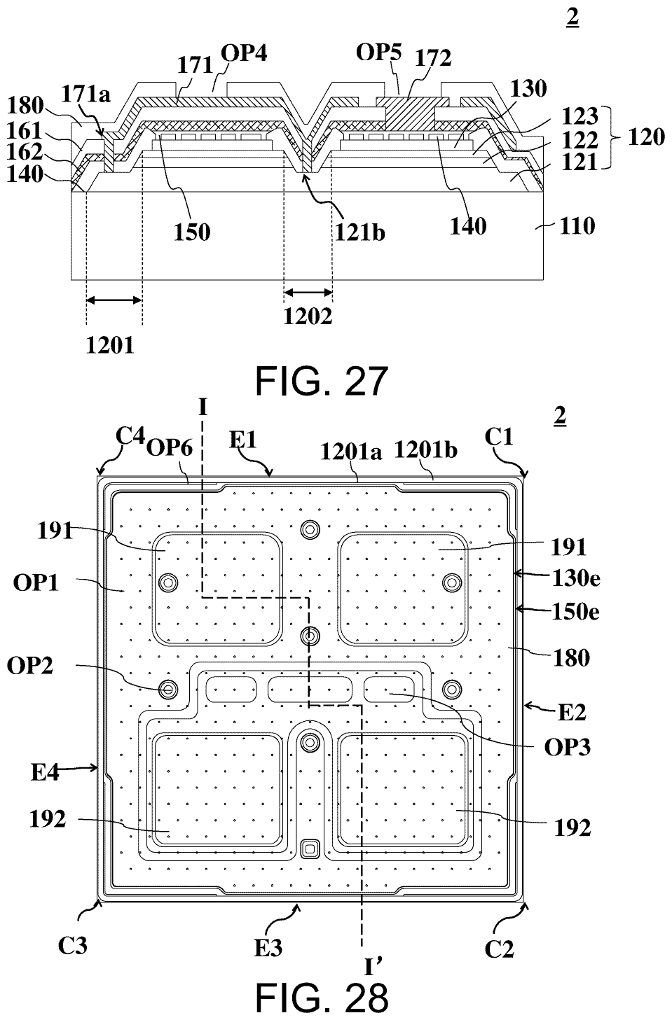

Following the connecting electrode 170 formation step, as shown in FIG. 26 and FIG. 27, wherein FIG. 27 is the cross-sectional view along segment I-I′ in the top view FIG. 26, the manufacturing method of the light emitting diode includes a step of forming a third insulating layer 180. The third insulating layer 180 is formed on the semiconductor stack 120 by a physical vapor deposition method, a chemical vapor deposition method, or other similar techniques. The third insulating layer 180 is then patterned through photolithography and etching to form a fourth opening portion OP4 and a fifth opening portion OP5, which expose the first connecting electrode 171 and the second connecting electrode 172, respectively.

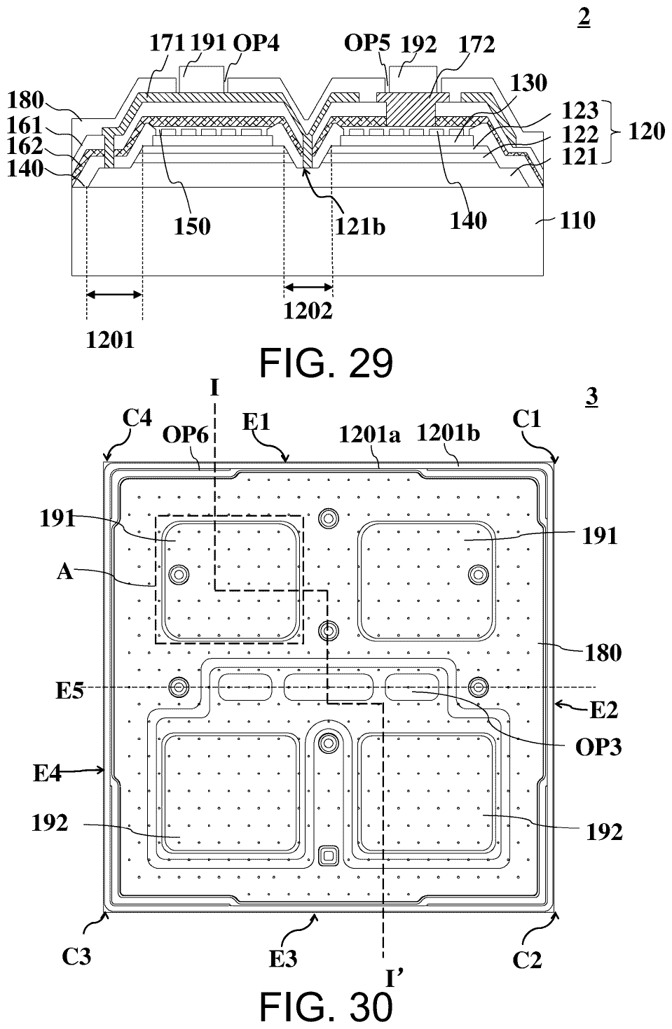

Following the third insulating layer formation step, the manufacturing method of the light emitting diode includes a step of forming pad electrodes 190. As shown inFIG. 28 and FIG. 29, wherein FIG. 29 is the cross-sectional view along segment I-I′ in the top view FIG. 28, a first pad electrode 191 and a second pad electrode 192 are formed on one or more semiconductor stacks 120 by electroplating, a physical vapor deposition method, a chemical vapor deposition method, or other similar techniques.

The first pad electrode 191 contacts the first connecting electrode 171 through the fourth opening portion OP4 and is electrically connected to the first semiconductor layer 121 through the first connecting electrode 171. The second pad electrode 192 contacts the second connecting electrode 172 through the fifth opening portion OP5 and is electrically connected to the second semiconductor layer 123 through the second connecting electrode 172. A projection of the first pad electrode 191 in the growth direction of the semiconductor stack 120 is located within the first connecting electrode 171. A projection of the second pad electrode 192 in the growth direction of the semiconductor stack 120 is located within the second connecting electrode 172. The area of the fourth opening portion OP4 is greater than the area of the first pad electrode 191, and the area of the fifth opening portion OP5 is greater than the area of the second pad electrode 192. This structural configuration allows the first pad electrode 191 and the second pad electrode 192 to be positioned on the same horizontal plane, reducing the die bonding void rate during light emitting diode packaging and enhancing heat dissipation performance.

In another embodiment of the disclosure, as shown in FIGS. 3 and 28, the light emitting diode 2 includes multiple corners and multiple edges, wherein any corner is formed by two adjacent edges. The multiple corners include a first corner C1, a second corner C2, a third corner C3, and a fourth corner C4. The multiple edges include a first edge E1, a second edge E2, a third edge E3, and a fourth edge E4. The first edge E1 and the third edge E3 may face each other, while the second edge E2 and the fourth edge E4 may face each other. The first corner C1 is adjacent to the first edge E1 and the second edge E2, the second corner C2 is adjacent to the second edge E2 and the third edge E3, the third corner C3 is adjacent to the third edge E3 and the fourth edge E4, and the fourth corner C4 is adjacent to the fourth edge E4 and the first edge E1. The first corner C1 and the fourth corner C4 are relatively close to the first pad electrode 191, while the second corner C2 and the third corner C3 are relatively close to the second pad electrode 192.

In an embodiment of the disclosure, as shown in FIGS. 3 and 28, the first mesa 1201 is located at an edge of the semiconductor stack 120. The first mesa 1201 continuously surrounds the second semiconductor layer 123 and the active layer 122 of the semiconductor stack 120 by continuously exposing the first surface 121a of the outermost first semiconductor layer 121 of the semiconductor stack 120.

In another embodiment of the disclosure, the first mesa 1201 is located at an edge of the semiconductor stack 120. The first mesa 1201 discontinuously surrounds the second semiconductor layer 123 and the active layer 122 of the semiconductor stack 120 by discontinuously exposing (i.e., exposing at least some areas while not exposing at least some other areas) the first surface 121a of the outermost first semiconductor layer 121 of the semiconductor stack 120.

As shown in FIGS. 3, 4, and 28, the first mesa 1201 may include a first platform 1201a and a second platform 1201b to continuously surround the semiconductor stack 120. A horizontal distance between an upper edge of the second outer sidewall 1200b of the first platform 1201a and an edge of the light emitting diode (e.g., the first edge E1) is a first distance D1. A horizontal distance between an upper edge of the second outer sidewall 1200b of the second platform 1201b and an edge of the light emitting diode (e.g., the first edge E1) is a second distance D2. In an embodiment, the first distance D1 is smaller than the second distance D2, which may increase the light-emitting area of the light emitting diode and enhance the brightness of the light emitting diode. The first distance D1 is in a range of 10 μm to 30 μm, and the second distance D2 is in a range of 20 μm to 40 μm.

In another embodiment of the disclosure, the first mesa 1201 may include only the second platform 1201b to continuously surround the semiconductor stack 120. A distance between the second platform 1201b and an edge of the light emitting diode (e.g., the first edge E1) is the second distance D2.

In another embodiment of the disclosure, the first mesa 1201 may include only the second platform 1201b to discontinuously surround the semiconductor stack 120. A distance between the second platform 1201b and an edge of the light emitting diode (e.g., the first edge E1) is the second distance D2.

In an embodiment of the disclosure, the second platform 1201b is located at the four corners of the light emitting diode 2. As shown in FIG. 3, the second platform 1201b has an L-shape, including a first section and a second section. The second platform 1201b is positioned closer to the corners of the light emitting diode 2 relative to the first platform 1201a.

As shown in FIGS. 17, 20, and 28, the fourth insulating layer 162 and the second insulating layer 161 contact and cover the first insulating layer 140. As a result, the first outer sidewall 1200a, the second outer sidewall 1200b, and the first surface 121a of the first mesa 1201, which are covered by the first insulating layer 140, are also covered by the fourth insulating layer 162 and the second insulating layer 161. The fourth insulating layer 162 and the second insulating layer 161 may protect the sidewalls of the semiconductor stack 120, preventing the active layer 122 from being damaged during subsequent fabrication processes. The fourth insulating layer 162 and the second insulating layer 161 also include a sixth opening portion OP6. The sixth opening portion OP6 is located on the first mesa 1201 of the semiconductor stack 120, exposing the first surface 121a of the first semiconductor layer 121. Specifically, a projection of the sixth opening portion OP6 in the growth direction of the semiconductor stack 120 is located within the second platform 1201b. The first connecting electrode 171 may discontinuously contact the first semiconductor layer 121 of the first mesa 1201 through the sixth opening portion OP6, enhancing the current diffusion of the light emitting diode.

In an embodiment of the disclosure, as shown in FIGS. 23, 24, and 25, a sidewall 171e of the first connecting electrode 171, which is close to the edge of the light emitting diode, is located on the first mesa 1201 or the second mesa 1202. That is, a projection of the first connecting electrode 171 in the growth direction of the semiconductor stack 120 is located within the first mesa 1201 or the second mesa 1202, effectively reducing the risk of a short circuit.

In an embodiment of the disclosure, the sixth opening portion OP6 may be an L-shape including a first section OP61 and a second section OP62, wherein the first section OP61 and the second section OP62 form a continuous structure. Since the fourth insulating layer 162 is aluminum oxide prepared by atomic layer deposition, and aluminum oxide has high stress, there is a risk of aluminum oxide peeling off from the first insulating layer 140 during the die-splitting process of the light emitting diode, especially at the four corner edges of the light emitting diode. Therefore, by providing the sixth opening portion OP6 at the four corners of the light emitting diode, the stress of the aluminum oxide may be relieved, thereby reducing the risk of aluminum oxide detaching from the first insulating layer 140. Additionally, since the sixth opening portion OP6 is located at the four corner edges of the light emitting diode 2, only the third insulating layer 180 remains at the four corners of the light emitting diode, reducing the occurrence of silicon chipping defects during stealth dicing. The sixth opening portion OP6 at the first corner C1 has the first section extending along the first edge E1 of the light emitting diode and the second section extending along the second edge E2 of the light emitting diode. The sixth opening portion OP6 at the second corner C2 has the first section extending along the second edge E2 of the light emitting diode and the second section extending along the third edge E3 of the light emitting diode. The sixth opening portion OP6 at the third corner C3 has the first section extending along the third edge E3 of the light emitting diode and the second section extending along the fourth edge E4 of the light emitting diode. The sixth opening portion OP6 at the fourth corner C4 has the first section extending along the fourth edge E4 of the light emitting diode and the second section extending along the first edge E1 of the light emitting diode.

In an embodiment of the disclosure, the area of the first surface 121a of the first semiconductor layer 121 exposed by the sixth opening portion OP6 located at the first corner C1 or the fourth corner C4 is greater than the area of the first surface 121a of the first semiconductor layer 121 exposed by the sixth opening portion OP6 located at the second corner C2 or the third corner C3.

In an embodiment of the disclosure, as shown in FIG. 17, the first section and the second section of the sixth opening portion OP6 located at the second corner C2 or the third corner C3 may be equal. By increasing the length of the second section, the contact area between the first connecting electrode 171 and the first semiconductor layer 121 may be increased, thereby enhancing current diffusion.

In an embodiment of the disclosure, as shown in FIG. 17, the first section and the second section of the sixth opening portion OP6 located at the first corner C1 or the fourth corner C4 may not be equal. By reducing the length of the second section, the light-emitting area of the light emitting diode 2 may be increased, thereby improving the brightness of the light emitting diode 2.

In an embodiment of the disclosure, the sixth opening portion OP6 may be formed using ICP dry etching. An included angle, referred to as the third included angle, is formed between the sidewall of the sixth opening portion OP6 and the first surface 120b of the first semiconductor layer 121. The third included angle is greater than the second included angle α2.

### Third Embodiment

FIG. 30 is a top view of a light emitting diode 3 disclosed in a third embodiment of the disclosure. FIG. 31 is a partially enlarged schematic diagram of FIG. 30. FIG. 32 is a cross-sectional view of the light emitting diode 3 along segment I-I′ of FIG. 30. FIG. 33 is a partially enlarged schematic diagram of FIG. 32.

The light emitting diode 3 has a structure that is substantially the same as that of the light emitting diode 1 or the light emitting diode 2. Therefore, for the structures of the light emitting diode 3 in FIGS. 30 and 31 that have the same names and reference numerals as those of the light emitting diode 1 or the light emitting diode 2 in FIGS. 1 to 29, they represent the same structures, have the same materials, or have the same functions. Accordingly, descriptions will be appropriately omitted or not repeated here.

In the manufacturing process of the third insulating layer 180 and the pad electrodes in the light emitting diode 1 or the light emitting diode 2, two photolithography processes are performed. Due to process issues such as exposure misalignment, different spacings exist between the pad electrodes and adjacent insulating layer opening portions. The pad electrodes may even overlap the third insulating layer 180, resulting in an uneven surface morphology of the pad electrodes 190. This increases the risk of a high void rate during the packaging stage of the light emitting diode. Additionally, due to the two photolithography processes, factors such as photomask linewidth variations and lateral etching of the insulating layer during etching processes generally cause the spacing between the third insulating layer 180 and the pad electrodes 190 to be greater than 5 μm, reducing the area of the pad electrodes 190.

Therefore, as shown in FIGS. 30 to 33, the third insulating layer 180 and the pad electrodes are fabricated using a same photolithography process, achieving self-aligned evaporation of the pad electrodes. The first pad electrode 191 has the same spacing from the adjacent fourth opening portions OP4, and the second pad electrode 192 has the same spacing from the adjacent fifth opening portions. Specifically, the first pad electrode 191 has an upper edge 191a away from the semiconductor stack 120 and a lower edge 191b close to the semiconductor stack 120. The second pad electrode 192 has an upper edge away from the semiconductor stack 120 and a lower edge close to the semiconductor stack 120. A first maximum horizontal distance D5 exists between the lower edge 191b of the first pad electrode 191 and the edge of the fourth opening portion OP4. The first maximum horizontal distance D5 is less than 5 μm. Due to measurement tool errors and other inaccuracies, a first minimum horizontal distance D6 exists between the edge of the first pad electrode 191 and the edge of the fourth opening portion OP4. The first minimum horizontal distance D6 is 50% to 150% of the first maximum horizontal distance D5. A second maximum horizontal distance exists between a lower edge 192b of the second pad electrode 192 and the edge of the fifth opening portion OP5. The second maximum horizontal distance is less than 5 μm. A second minimum horizontal distance exists between the edge of the second pad electrode 192 and the edge of the fifth opening portion OP5. The second minimum horizontal distance is 50% to 150% of the second maximum horizontal distance.

In an embodiment of the disclosure, as shown in FIGS. 30 to 33, the surfaces of the first pad electrode 191 and the second pad electrode 192 that are away from the semiconductor stack 120 are higher than the surface of the third insulating layer 180 that is away from the semiconductor stack 120.

In an embodiment of the disclosure, as shown in FIGS. 30 to 33, the first edge E1 is relatively closer to the first pad electrode 191, while the third edge E3 is relatively farther from the first pad electrode 191. The first edge E1 and the third edge E3 are parallel. A virtual parallel line E5 is drawn parallel to the first edge E1 and the third edge E3, passing through the midpoint between the first edge E1 and the third edge E3. The number of second mesas 1202 adjacent to the first edge E1 is greater than the number of second mesas 1202 adjacent to the third edge E3. This maximizes current spreading while also enlarging the area of the second pad electrode 192 as much as possible, ensuring that the areas of the first pad electrode 191 and the second pad electrode 192 remain equal and symmetrical.

In another embodiment of the disclosure (not shown in the figures), the area of the second surface 121b of the first semiconductor layer 121 exposed by the second mesas 1202 adjacent to the first edge E1 is greater than the area of the second surface 121b of the first semiconductor layer 121 exposed by the second mesas 1202 adjacent to the third edge E3. The number of second mesas 1202 adjacent to the first edge E1 and the number of second mesas 1202 adjacent to the third edge E3 may be the same or different.

### Fourth Embodiment

FIG. 34 is a cross-sectional view of a light emitting diode 4 disclosed in a fourth embodiment of the disclosure.

The light emitting diode 4 has a structure that is substantially the same as that of the light emitting diode 1, 2, or 3. Therefore, for the structures of the light emitting diode 4 in FIG. 34 that have the same names and reference numerals as those of the light emitting diode 1, 2, or 3 in FIGS. 1 to 33, they represent the same structures, have the same materials, or have the same functions. Accordingly, descriptions will be appropriately omitted or not repeated here.

As shown in FIG. 34, to enhance the current spreading effect of the light emitting diode, particularly in elements of high-current products, a metal layer 210 is provided between the reflective electrode layer 150 and the fourth insulating layer 162. The metal layer 210 is formed on the reflective electrode layer 150, i.e., on the upper portion R1 of the metal protective layer 152. A projection of the metal layer 210 in the growth direction of the semiconductor stack 120 is located within a projection of the reflective electrode layer 150. A horizontal distance between the sidewall of the metal layer 210 and the second outer sidewall 1200b or the inner sidewall 1200c of the semiconductor stack 120 is a seventh distance D7. The seventh distance D7 is greater than the fourth distance D4. The metal layer 210 may be composed of one or more highly conductive metals such as titanium, platinum, nickel, or gold.

What is claimed is:

1. A light emitting diode, comprising:
a semiconductor stack, comprising, from a bottom to a top, a first semiconductor layer, a second semiconductor layer, and an active layer located between the first semiconductor layer and the second semiconductor layer;
a first insulating layer, formed on the semiconductor stack, wherein the first insulating layer has an upper surface away from the semiconductor stack and a lower surface opposite to the upper surface, wherein the upper surface has a first surface, a second surface, and a third surface connected to the first surface and the second surface, and a thickness between the first surface and the lower surface is less than a thickness between the second surface and the lower surface;
a reflective electrode layer, formed on the first insulating layer, wherein an edge of the reflective electrode layer is formed on the third surface of the first insulating layer, a horizontal distance between the edge of the reflective electrode layer and an edge of the second semiconductor layer is a fourth distance, and the fourth distance is in a range of 1 μm to 5 μm; and
a fourth insulating layer, formed on the reflective electrode layer and extending to the second surface of the first insulating layer, wherein the fourth insulating layer is aluminum oxide.

2. The light emitting diode according to claim 1, further comprising a second insulating layer and at least one mesa, wherein the at least one mesa is located inside the semiconductor stack and/or in an edge region, and at least exposes a part of surface of the first semiconductor layer;
the second insulating layer is formed on the fourth insulating layer, and a thickness of the second insulating layer is greater than a thickness of the fourth insulating layer.

3. The light emitting diode according to claim 1, wherein a thickness between a surface of the reflective electrode layer away from the semiconductor stack and the lower surface of the first insulating layer is less than a thickness between the second surface of the first insulating layer and the lower surface.

4. The light emitting diode according to claim 1, wherein the reflective electrode layer comprises a metal reflective layer and a metal protective layer, wherein the metal protective layer comprises an upper portion formed on an upper surface of the metal reflective layer and a side portion formed on a side surface of the metal reflective layer.

5. The light emitting diode according to claim 4, wherein a thickness of the metal reflective layer is in a range of 100 nm to 200 nm, and a thickness of the metal protective layer is in a range of 100 nm to 500 nm.

6. The light emitting diode according to claim 1, further comprising a transparent conductive layer formed on the semiconductor stack, wherein a horizontal distance between a sidewall of the transparent conductive layer and an edge of an upper surface of the second semiconductor layer is a third distance, and the third distance is greater than the fourth distance.

7. The light emitting diode according to claim 6, wherein the third distance is in a range of 2 μm to 6 μm.

8. The light emitting diode according to claim 2, wherein the fourth insulating layer and the second insulating layer comprise a second opening portion and a third opening portion, wherein the second opening portion exposes a part of surface of the first semiconductor layer, and the third opening portion exposes a part of surface of the reflective electrode layer, wherein a first included angle is formed between a sidewall of the second opening portion and a surface of the first semiconductor layer, a second included angle is formed between a sidewall of the third opening portion and a surface of the reflective electrode layer, and the first included angle is greater than the second included angle.

9. The light emitting diode according to claim 2, wherein the fourth insulating layer and the second insulating layer comprise a sixth opening portion exposing a part of surface of the first semiconductor layer, and the sixth opening portion is located on the mesa in the edge region of the semiconductor stack.

10. The light emitting diode according to claim 9, wherein the sixth opening portion comprises a first section and a second section, and the first section and the second section is a continuous structure.

11. The light emitting diode according to claim 8, further comprising a first connecting electrode and a second connecting electrode, wherein the first connecting electrode is electrically connected to the first semiconductor layer through the second opening portion, and the second connecting electrode is electrically connected to the second semiconductor layer through the third opening portion.

12. The light emitting diode according to claim 11, wherein a projection of an outer edge of the first connecting electrode in a growth direction of the semiconductor stack is located within the mesa.

13. The light emitting diode according to claim 1, wherein a thickness of the fourth insulating layer is in a range of 10 nm to 150 nm.

14. The light emitting diode according to claim 1, wherein the first insulating layer has a plurality of first opening portions, and the reflective electrode layer is electrically connected to the second semiconductor layer through the first opening portion.

15. The light emitting diode according to claim 14, wherein the third surface of the first insulating layer is an inclined surface relative to the first surface of the first insulating layer and the second surface of the first insulating layer, and the first surface and the second surface are parallel to each other.

16. The light emitting diode according to claim 1, further comprising a metal layer, wherein the metal layer is located between the reflective electrode layer and the fourth insulating layer, a projection of the metal layer in a growth direction of the semiconductor stack is located in the reflective electrode layer, and an edge of the metal layer is located on an upper surface of the reflective electrode layer.

17. The light emitting diode according to claim 11, further comprising a third insulating layer, wherein the third insulating layer is formed on the first connecting electrode and the second connecting electrode, the third insulating layer having a fourth opening portion and a fifth opening portion, wherein the fourth opening portion exposes a part of surface of the first connecting electrode, and the fifth opening portion exposes a part of surface of the second connecting electrode.

18. The light emitting diode according to claim 17, further comprising a first pad electrode and a second pad electrode, wherein the first pad electrode is electrically connected to the first semiconductor layer, the second pad electrode is electrically connected to the second semiconductor layer, the first pad electrode is located in the fourth opening portion, and the second pad electrode is located in the fifth opening portion.

19. The light emitting diode according to claim 18, wherein there is a first maximum horizontal distance between the first pad electrode and the fourth opening portion, and there is a first minimum horizontal distance between the first pad electrode and the fourth opening portion, the first minimum horizontal distance being 50% to 150% of the first maximum horizontal distance, wherein there is a second maximum horizontal distance between the second pad electrode and the fifth opening portion, and there is a second minimum horizontal distance between the second pad electrode and the fifth opening portion, the second minimum horizontal distance being 50% to 150% of the second maximum horizontal distance.

20. The light emitting diode according to claim 1, wherein the fourth insulating layer contacts the reflective electrode layer.
